(19) United States
(12) Patent Application Publication
(10) Pub. No.: US 2007/0034970 A1
(43) Pub. Date: Feb. 15, 2007

(54) Semiconductor device and method of fabricating the same

(75) Inventors: You-Seung Jin, Seoul (KR); Joon-Won Jeon, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/501,259

(22) Filed: Aug. 9, 2006

(30) Foreign Application Priority Data
Aug. 10, 2005 (KR) 10-2005-0073411

(51) Int. Cl. H01L 29/76

(52) U.S. Cl. 257/393

(57) ABSTRACT

The semiconductor device comprises a semiconductor substrate having a first active region, wherein the first active region includes a recessed region, a first gate formed on a channel between impurity regions formed on the first active region, and a second gate having a recessed upper surface, wherein a profile of the recessed upper surface is substantially the same as a profile of the recessed region.

### CROSS-REFERENCE TO RELATED PATENT APPLICATIONS

This application claims priority to Korean Patent Application No. 10-2005-7341 1, filed on Aug. 10, 2005, the disclosure of which is herein incorporated by reference in its entirety.

### BACKGROUND OF THE INVENTION

1. Technical Field

The present disclosure relates to a semiconductor device and a method for fabricating the same, and, more particularly, to a semiconductor device having improved reliability, and a method of fabricating the same.

2. Discussion of the Related Art

As the size of semiconductor devices continues to decrease, the chip integration density increases. While active power remains constant in the scaling, the chip leakage power increases and becomes one of the challenges in CMOS design. A shared contact that connects a gate and an active region can be used in semiconductor memory devices such as a SRAM or semiconductor logic devices such as a CPU.

However, when forming a shared contact hole for the shared contact, excessive etching of the spacer surrounding the sidewall of the gate can occur by the gap between the gate and the active region. The occurrence of pitting on the active region formed on a lower part of a spacer can be a cause of a junction current leakage of a pull-up transistor. The junction current leakage can degrade the reliability of semiconductor devices, for example, by lowering the static noise margin (SNM) of SRAM cells.

### SUMMARY OF THE INVENTION

According to an exemplary embodiment of the present invention, a semiconductor device comprises: a semiconductor substrate having a first active region, wherein the first active region includes a recessed region; a first gate formed on a channel between impurity regions formed on the first active region, and a second gate having a recessed upper surface, wherein a profile of the recessed upper surface is substantially the same as a profile of the recessed region.

According to an exemplary embodiment of the present invention, a method for fabricating a semiconductor device comprises providing a semiconductor substrate having a first active region, forming a recessed region in the first active region, forming a first gate and a second gate, wherein the first gate and the second gate have a recessed upper surface according to the profile of the recessed region in the first active region, and forming impurity regions in the first active region exposed by the first and second gates.

### BRIEF DESCRIPTION OF THE DRAWINGS

The present invention will become readily apparent to those of ordinary skill in the art when descriptions of exemplary embodiments thereof are read with reference to the accompanying drawings.

FIG. 1 is a circuit diagram illustrating a semiconductor device according to an exemplary embodiment of the present invention.

FIG. 2A is a plane view illustrating a layout of a semiconductor device according to an exemplary embodiment of the present invention.

FIG. 2B is a cross-sectional view taken along the I-I′ line of FIG. 2A.

FIG. 3 is a flow chart illustrating a semiconductor device fabrication method according to an exemplary embodiment of the present invention.

FIGS. 4A through 8A are layouts illustrating the semiconductor device semiconductor device fabrication method according an exemplary embodiment of the present invention.

FIGS. 4B through 8B are cross-sectional views taken along the I-I′ line illustrating the semiconductor device semiconductor device fabrication method according to an exemplary embodiment of the present invention.

### DESCRIPTION OF EXEMPLARY EMBODIMENTS

Hereinafter, exemplary embodiments of the present invention will be described in detail with reference to the accompanying drawings.

Like reference numerals refer to similar or identical elements throughout the description of the figures.

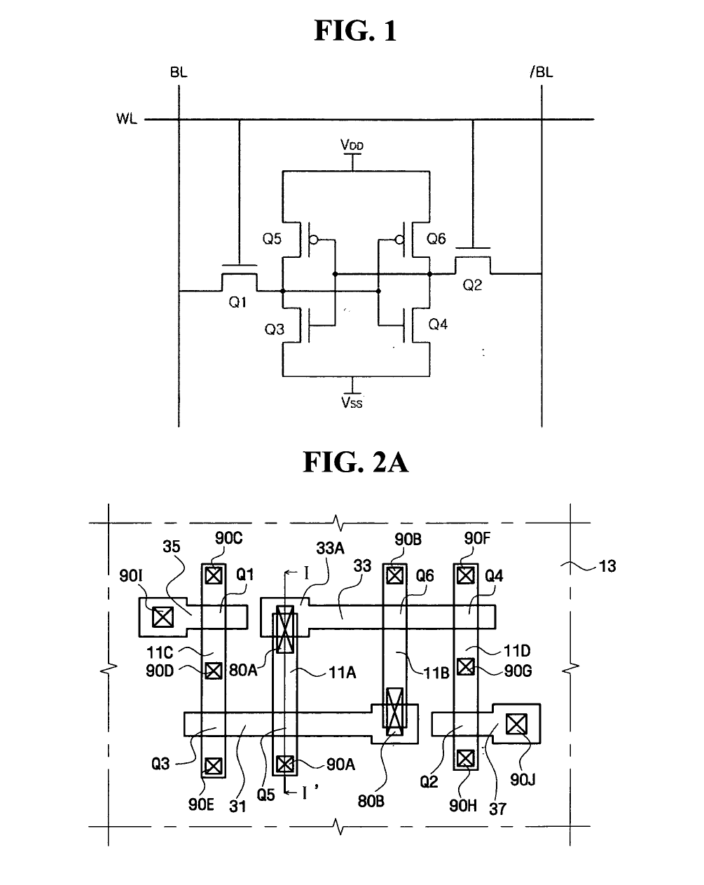

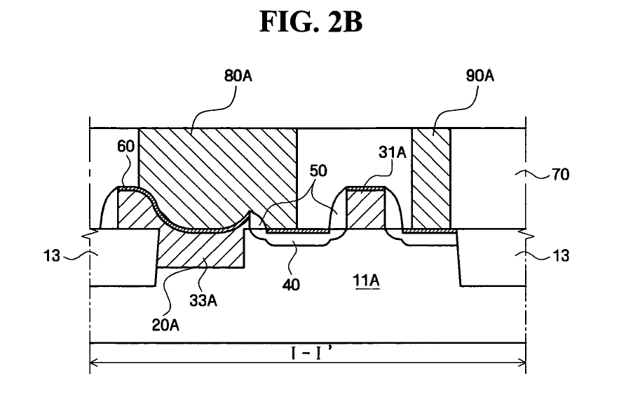

Hereinafter, a semiconductor device according to an exemplary embodiment of the present invention will be described with reference to FIGS. 1 and 2.

FIG. 1 is a circuit diagram illustrating a semiconductor device according to an exemplary embodiment of the present invention.

Referring to FIG. 1, the semiconductor device comprises a CMOS SRAM device. For example, one cell of the CMOS SRAM device includes a first and a second pass transistor Q1 and Q2, a first and a second pull-down transistor Q3 and Q4, and a first and a second pull-up transistor Q5 and Q6.

As shown in FIG. 1, the sources of the first and the second pull-down transistors Q3 and Q4 are connected to a ground wire V_{SS}, and the sources of the first and the second pull-up transistors Q5 and Q6 are connected to a power line V_{DD}.

The first pull-down transistor Q3, which may be an NMOS transistor, and the first pull-up transistor Q5, which may be a PMOS transistor, comprise a first inverter. The second pull-down transistor Q4, which may be an NMOS transistor, and the second pull-up transistor Q6, which may be a PMOS transistor, comprise a second inverter.

The output terminals of the first and second inverters are respectively connected to the sources of the first pass transistor Q1 and the second pass transistor Q2. The input terminals and the output terminal of the first and second inverters are cross-connected in the standard configuration for forming a latch circuit.

As shown in FIG. 1, the drains of the first and second pass transistors Q1 and Q2 are connected to the first and second bit lines BL /BL, respectively.

FIG. 2A is a plan view illustrating a layout of a semiconductor device according to an exemplary embodiment of the present invention. FIG. 2B is a cross-sectional view taken along the I-I′ line in FIG. 2A.

As illustrated in FIGS. 2A and 2B, a semiconductor according to an exemplary embodiment of the present invention includes a first active region 11 A defined by a device separation region 13. A first gate 31 and a second gate 33 are disposed on the upper part of the first active region 11A. The first gate 31 is formed to pass the upper part of the channel region between impurity regions formed on the first active region 11A, forming the first pull-up transistor Q5 on the first active region 11A. The end part 33A of the second gate 33 crosses an end part of the first active region 11A, which is formed adjacently to an impurity region formed on the first active region 11A.

The first active region 11A can include a shared contact 80A between the second gate 33 and the adjacent impurity region.

Referring to FIG. 2B, the above-described first active region 11A includes a recessed region 20A.

The second gate 33A is formed to cover the recessed region 20A. The upper surface of the second gate 33A has a recessed structure that looks like generally a profile of the recessed region 20A formed in the first active region 11A, and the gap between the second gate 33A and the upper surface of an adjacent active region may be reduced. When a shared contact, which connects the second gate 33A and the impurity region 40, is formed on the adjacent active region, according to an exemplary embodiment of the present invention, the occurrence of pitting of the active region by the gap between the gate and the active region can be minimized.

The above-described recessed region 20A can be formed in the active region 11A adjacent to an element separation region 13. The depth of the recessed region 20A may be about 500 Å to about 3000 Å from the upper surface of the active region. It is to be understood that the depth of the recessed region 20A can be appropriately adjusted.

A semiconductor device according to an exemplary embodiment of the present invention can include a metal contact 90A. The impurity region 40 formed on the first active region 11A can be an LDD structure, and a silicide layer 60 can be formed on the upper surface of the impurity region 40 and/or the upper surface of the gate. The silicide layer can comprise a metal such as Co, Ni, Ti and other metals, or a combination of such metals.

The reference numeral 70 indicates a dielectric interlayer. Although not shown as such in the drawings, a gate dielectric can be formed on the lower part of the first and second gates.

Referring to FIG. 2A, the semiconductor device according to an exemplary embodiment of the present invention can include a second active region 11B that is independent of the first active region 11A. For example, the second active region 11B can be formed to be parallel to but separate from the first active region 11A. The second gate 33 can be extended to cross the second active region 11B, and the second gate 33 can form a transistor Q6 on the secorid active region, for example, a second pull-up transistor.

Here, a structure formed on the second active region 11B is substantially similar to a structure formed on the first active region 11A, but can be symmetrical. For example, the second active region 11B can be recessed substantially similar to the first active region 11A, and the extended first gate 31, which crosses the second active region 11B, can cross over the recessed region, and the gap between the extended first gate 31 and the second active region 11B may be reduced. In addition, a shared contact 80B between the extended first gate 31 and the adjacent impurity region can be formed on the second active region 11B.

The structure of the second active region 11B is the same as that of the second active region 11A except for the relative arrangement, and the structures of both active regions are substantially similar. Thus, further descriptions thereof will be omitted in the interests of clarity and simplicity.

A semiconductor device according to an exemplary embodiment of the present invention can include a third active region 11C and a fourth active region 11D, which are independent of the first active region 11A and the second active region 11B. The third active region 11C is parallel to the first active region 11A, and can be disposed in the region opposite to the second active region 11B centered on the first active region 11A. Also, the fourth active region 11D is parallel to the second active region 11B, and can be disposed in the region opposite to the first active region 11A centered on the second active region 11B.

The first gate 31 can be extended to comprise a transistor Q3 on the third active region 11C, for example, a first pull-down transistor. Also, the second gate 31 can be extended to comprise a transistor Q4 on the fourth active region 11D, for example, a second pull-down transistor.

The third active region 11C and the fourth active region 11D can have a separate transistor including third and fourth gates that are independent of the first and second gates. For example, the third active region 11C can have a transistor Q1 including the third gate 35, and the fourth active region 11D can have a transistor Q2 including the fourth gate 37.

In FIG. 2A, reference numerals 90A through 90J correspond to metal contacts.

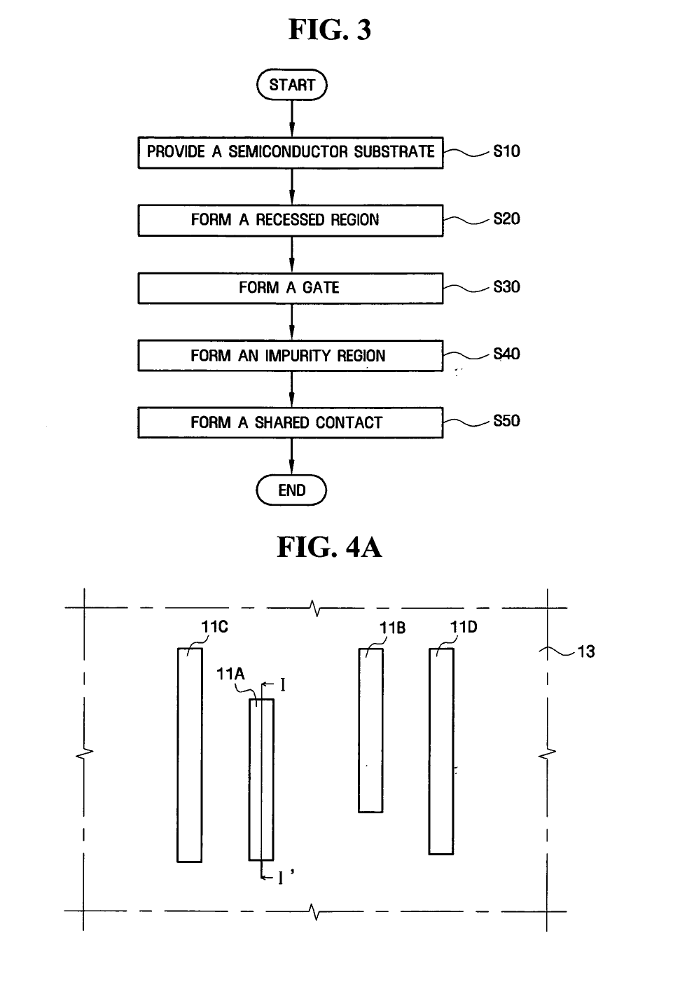

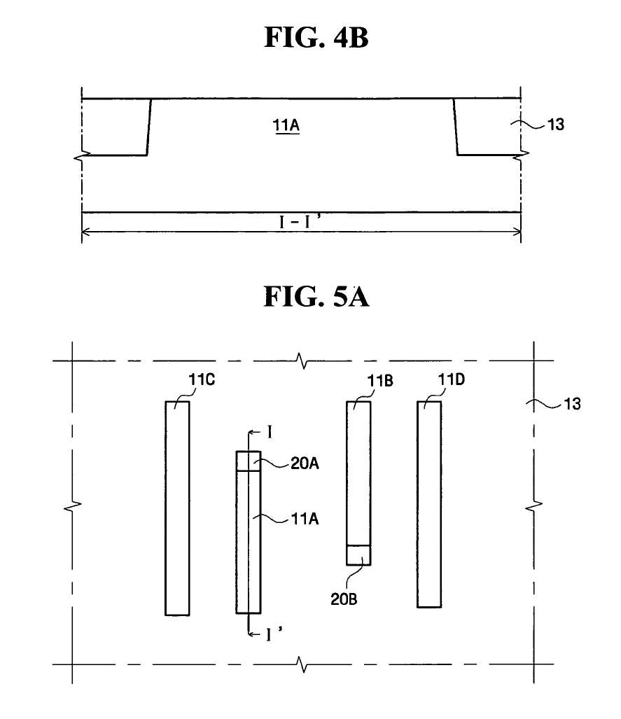

Hereinafter, a semiconductor-device fabrication method according to an embodiment of the present invention will be described in detail with reference to FIG. 3, FIGS. 4A-8A and FIGS. 4B-8B.

FIG. 3 is a flow chart illustrating a semiconductor-device fabrication method according to an exemplary embodiment of the present invention. FIGS. 4A through 8A are layouts illustrating the semiconductor-device fabrication method according an exemplary embodiment of the present invention. FIGS. 4B through 8B are cross-sectional views taken along the I-I′ line illustrating the semiconductor-device fabrication method according to an exemplary embodiment of the present invention.

First, a semiconductor substrate is provided in step S10.

Referring to FIG. 4A, the semiconductor substrate has a first active region 11A which is defined by a device separation region 13. A second active region 11B can be provided parallel to the first active region 11A. A third active region 11C can be provided opposite to the second active region 11B and centered on the first active region 11A. A fourth active region 11D can be provided opposite to the first active region 11A and centered on the second active region 11B. FIG. 4B illustrates a sectional view taken along the I-I′ line of FIG. 4A.

In step S20, a recessed region is formed in the first active region.

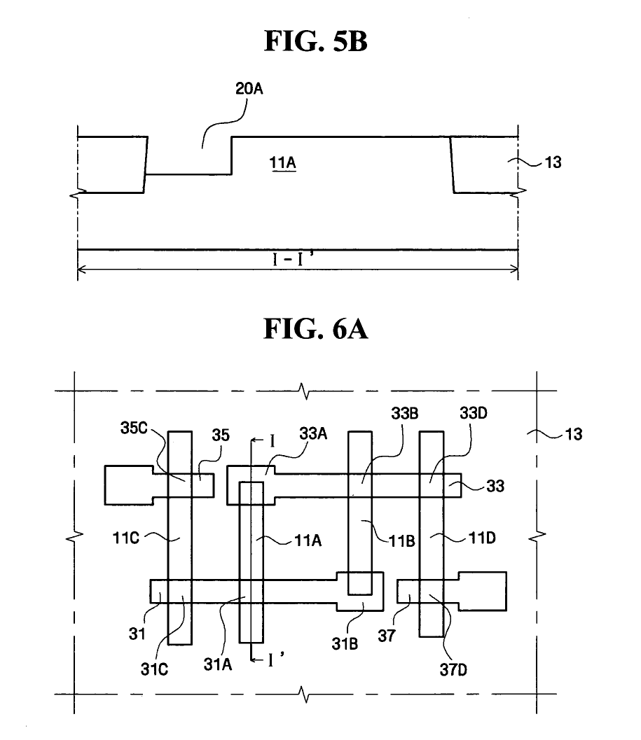

Referring to FIG. 5A, a recessed region 20A is formed in the first active region 11A. The recessed region 20B can be formed in the second active region 11B defined on the substrate. For example, the first active region 11A and the second active region 11B recessed region are symmetrical relative to each other.

As illustrated in FIG. 5B, the recessed region 20A can be formed to be adjacent to the device separation region 13. The recessed region 20A, which is formed on the active region, can be formed to a depth of about 500 Å to about 3000 Å It is to be understood that the depth of the recessed region 20A can be adjusted. FIG. 5B illustrates a section including the first active region 11A, but because it can be applied in a section including the second active region 11B in the same manner, further explanation of the second active region 11B will be omitted.

The method for forming a recessed region on each active region can be, for example, dry etching or wet etching. Because such methods are well known to those skilled in the art, further explanation thereof will be omitted.

Although not shown as such in the drawings, a gate dielectric can be formed on the upper surface of the active region including the recessed region.

In step S30, the first and second gates are formed.

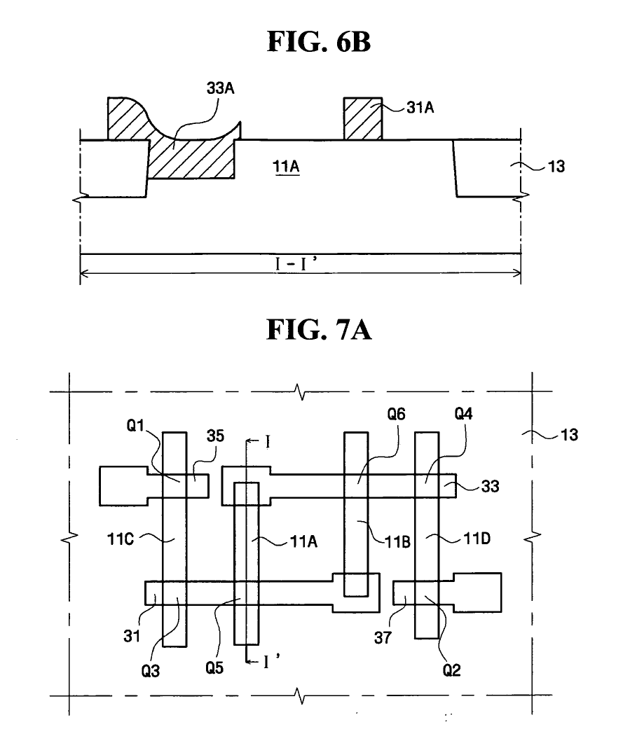

Referring to FIG. 6A, the first gate 31 is located so as to comprise a transistor on the first active region 11A by an impurity-region formation process for forming a region 31A crossed with the first active region 11A.

The second gate 33 is formed so that the end part 33A overlaps the end part of the first active region 11A. As shown in FIG. 6A, the end part 33A of the second gate 33 can be of a hammer form, which can be wider than a common gate line, for example, to secure a margin in processes.

Hereinafter, a section of the first and second gates, which is formed on the first active region 11A, will be described with reference to FIG. 6B.

Referring to FIG. 6B, the end part 33A of the second gate 33 is formed on a recessed region 20A formed on the first active region 11A, and can be formed to cover the device separation region and the active region. At this point, when gate materials, e.g., polysilicon, are deposited, the recessed region should be completely filled. The upper surface of the formed second gate can be recessed to the depth of the recessed region of the active region, reducing the gap between the second gate and the adjacent first active region.

The gate can be made of polysilicon, but other suitable materials can be used for implementing the gate.

As illustrated in FIG. 6A, the first gate 31 can be extended so that the end part 31B crosses an independent second active region 11B. The end part 31B of the first gate 31 can be located on the recessed region formed on the second active region 11B. Because a structure in the second active region 11B is substantially similar with the structure of the first active region 11A, further explanation thereof will be omitted.

The first gate 31 can be extended to form an independent transistor on the third active region 11C, which is parallel to but opposite the second active region, and a cross region 31C can be formed on the third active region 11C.

The second gate 33 is extended to comprise an independent transistor on the second active region 11B, and a cross region 33B with the second active region 11B can be formed. The second gate 33 can be further extended to form a transistor on the fourth active region 11D, which is located in parallel to and on the opposite side of the twelfth active region 11A, and a cross region 33D can be formed on the fourth active region 11D.

When the first and second gates are formed, the third gate 35 on the third active region 11C and the fourth gate on the fourth active region 11D can be formed at substantially the same time. The first gate 35 and the fourth gate 37 have an independent gate structure, and an independent transistor can be implemented on the third and the fourth regions. Because the methods for forming such gates are well known to those skilled in the art, further explanation thereof will be omitted.

In step S40, an impurity region is formed on each active region.

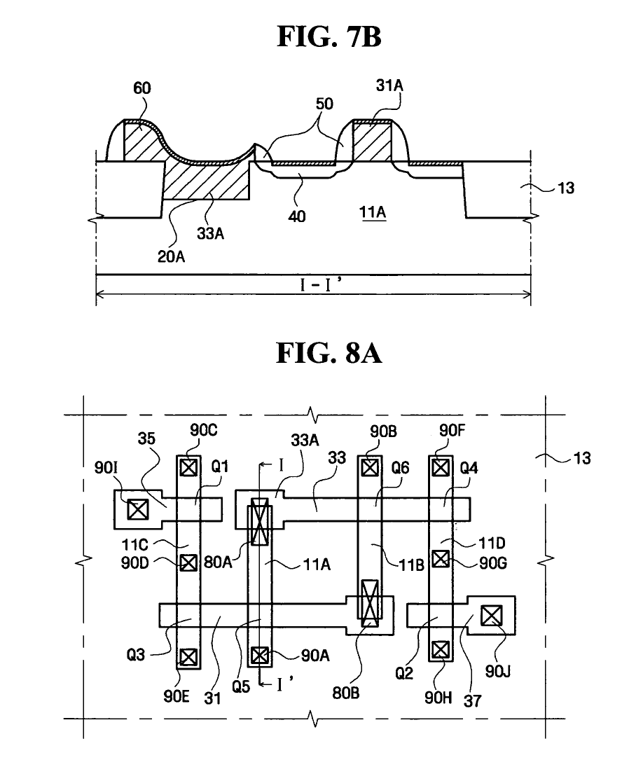

Referring to FIG. 7A, an impurity region is formed by implanting impurities into the first active region 11A exposed by the first gate 31 and the second gate 33, forming a transistor including the first gate 31 on the first active region 11A.

At substantially the same time an impurity region can be formed on the second active region 11B exposed by the first gate 31 and the second gate 33, forming a transistor Q6 including the second gate 33 on the second active region 11B.

An impurity region can be formed on the third active region 11C exposed by the first gate 31 and the third gate 35, forming a transistor Q3 including the first gate 31 and a transistor Q1 including the third gate 35 on the third active region. An impurity region can be formed on the fourth active region 11D exposed by the second gate 33 and the fourth gate 37, forming a transistor Q4 including the second gate 33 and a transistor Q2 including the fourth gate 37 on the fourth active region 11D.

Referring to FIG. 7B, such impurity regions can be an LDD structure. Before or after forming such impurity regions, a spacer 50 can be formed or silicide layers 60 can be formed on the upper part of the gate and impurity regions. The silicide layers 60 can comprise a metal, such as for example, Co, Ni, and Ti. Because an ion injection process for forming impurity regions and methods for forming a spacer and a silicide film are well known to those skilled in the art, the explanation thereof will be omitted.

A shared contact can be formed in step S50.

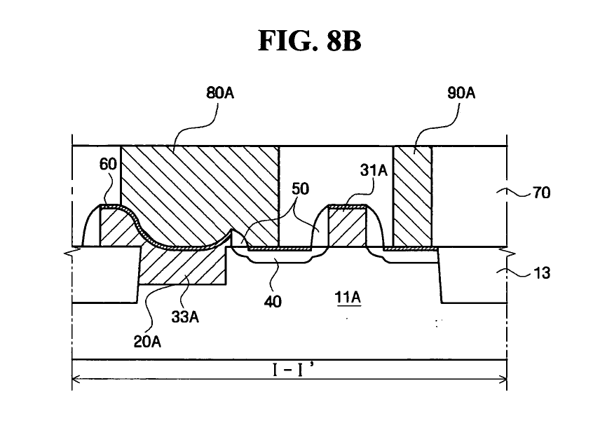

Referring to FIG. 8A, a shared contact 80A is formed that connects impurity regions adjacent to the second gate among the second gate 33A and impurity regions formed on the first active region 11A.

As illustrated in FIG. 8B, the shared contact 80A can connect the upper part of the second gate 33A and the adjacent impurity region 40.

At substantially the same time, a shared contact 80B connecting impurity regions adjacent to the first gate among impurity regions formed on the first gate 31 and the second active region 11B can be formed. Also, a metal contact 90A, which is not a shared-contact type, can also be formed on various conductive layers, and these shared contacts and metal contacts can be formed at substantially the same time. Because processes for forming shared contacts and metal contacts are well known to those skilled in the art, further explanation thereof will be omitted.

The semiconductor device fabrication can be completed by forming wiring for the input/output of each electric signal of each transistor, forming a passivation layer on a substrate, and packaging the substrate, which are steps well known to those skilled in the art. These steps have been roughly described so as to avoid being incorrectly interpreted.

According to exemplary embodiments of the present invention, the gate on the region where a shared contact is formed can be reduced and the gap between the gate and the active region can be reduced. The reliability of a semiconductor device fabricated according to exemplary embodiments of the present invention can be improved by reducing the occurrence of pitting of the active region when a shared contact is formed.

Although the exemplary embodiments of the present invention have been described in detail with reference to the accompanying drawings for the purpose of illustration, it is to be understood that the inventive processes and apparatus should not be construed as limited thereby. It will be readily apparent to those of reasonable skill in the art that various modifications to the foregoing exemplary embodiments can be made without departing from the scope of the invention as defined by the appended claims, with equivalents of the claims to be included therein.

What is claimed is:

1. A semiconductor device comprising:
a semiconductor substrate having a first active region, wherein the first active region includes a recessed region;
a first gate formed on a channel between impurity regions formed on the first active region; and
a second gate having a recessed upper surface, wherein a profile of the recessed upper surface is substantially the same as a profile of the recessed region.

2. The device of claim 1, wherein the recessed region is formed adjacent to a device separation region.

3. The device of claim 1, wherein the depth of the recessed region is about 500 Å to about 3000 Å.

4. The device of claim 1, further comprising:
a shared contact connecting the second gate and the adjacent impurity region on the first active region.

5. The device of claim 1, wherein the second gate comprises a transistor of a second active region, and wherein the second active region is independent of the first active region.

6. The device of claim 5, wherein the second active region includes a recessed region, and wherein the second gate is extended on the second active region to comprise a structure having a recessed upper surface, wherein a profile of the recessed upper surface is substantially the same as a profile of the recessed region.

7. The device claim 6, wherein the second gate is formed on a channel between impurity regions formed on the second active region, and wherein a shared contact connecting the first gate and the adjacent impurity region is included on the second active region.

8. The device of claim 5, wherein third and fourth active regions that are independent of the first and second active regions are defined in the semiconductor substrate.

9. The device of claim 8, wherein the first and second gates are extended to comprise at least one transistor on the third and fourth active regions, respectively.

10. The device of claim 9, wherein the third and fourth active regions each include at least one transistor.

11. A method for fabricating a semiconductor device, the method comprising:
providing a semiconductor substrate having a first active region;
forming a recessed region in the first active region;
forming a first gate and a second gate according to the profile of the recessed region in the first active region; and
forming impurity regions on the first active region exposed by the first and second gates.

12. The method of claim 11, wherein the recessed region is formed adjacent to a device separation region.

13. The method of claim 11, wherein the depth of the recessed region is about 500 Å to about 3000 Å.

14. The method of claim 11, further comprising:
forming a first shared contact connecting the second gate and the adjacent impurity region on the first active region.

15. The method of claim 11, wherein a second active region separated from the first active region is defined on the semiconductor substrate, and the second gate comprises a transistor of the second active region.

16. The method of claim 15, wherein the step of forming the recessed region in the first active region further comprises forming a recessed region in the second active region, and wherein the second gate is extended on the second active region so that the upper surface can have a recessed structure according to the profile of the recessed active region.

17. The method of claim 16, further comprising:
forming an impurity region on the second active region exposed by the first and second gates when forming the impurity region; and
forming a first shared contact connecting the second gate and the adjacent impurity region on the first active region, and forming a second shared contact connecting the first gate and the adjacent impurity region on the second active region after forming the impurity region.

18. The method of claim 15, further comprising forming third and fourth active regions that are independent of the first and second active regions on the semiconductor substrate.

19. The method of claim 18, wherein the step of forming the first and second gates comprises extending the first and second gates to the upper part of third and fourth active regions.

20. The method of claim 18, wherein the step of forming the first and second gates comprises forming a third gate on the third active region and a fourth gate on the fourth active region.

21. The method of claim 20, wherein the step of forming the impurity regions comprises forming impurity regions on a third active region exposed by the first and third gates and on the fourth active region exposed by the second and fourth gates.
